(19) United States
(12) Patent Application Publication
(10) Pub. No.: US 2014/0347563 A1
(43) Pub. Date: Nov. 27, 2014

(54) DISPLAY DEVICE AND TELEVISION RECEIVER

(71) Applicant: SHARP KABUSHIKI KAISHA, Osaka-shi, Osaka (JP)

(72) Inventors: Kenichiro Ito, Osaka-shi (JP); Hideto Takeuchi, Osaka-shi (JP); Yasufumi Gouma, Osaka-shi (JP)

(21) Appl. No.: 14/371,559

(22) PCT Filed: Sep. 21, 2012
(86) PCT No.: PCT/JP2012/074297

§ 371 Date: Jul. 10, 2014

(30) Foreign Application Priority Data
Jan. 13, 2012 (JP) 2012-005629
Sep. 20, 2012 (JP) 2012-207596

(51) Int. Cl. H05K 5/00; G02F 1/1335; H04N 5/44; H05K 1/02

(52) U.S. Cl. CPC H05K 5/0017; H05K 1/028; G02F 1/133602; H04N 5/44; H05K 2201/05; H05K 2201/04
USPC 348/725; 361/752; 362/97.1

(57) ABSTRACT

A display device includes: a backlight chassis; and a circuit substrate having a substrate rear surface facing the chassis with a circuit pattern formed on the substrate rear surface and having a part held with respect to the chassis, the chassis having a drawn part with which an edge of the source substrate makes contact when the source substrate is displaced.

### TECHNICAL FIELD

The present invention relates to a display device and a television receiver including a display device.

### BACKGROUND ART

As thin, lightweight, and low-power display devices capable of performing high image quality displays, display devices in which TFTs (thin-film transistors) are used have been widely used in personal computers, cellular phones, televisions, etc. Such a display device usually includes: a TFT substrate on which TFT elements are disposed; and a liquid crystal display panel obtained by sealing in liquid crystals between opposed substrates on which counter electrodes are disposed.

Formed on a TFT substrate of this liquid crystal display panel a plurality of gate wires to which scanning signals are applied and a plurality of source wires to which video signals are applied. The gate wires and the source wires demarcates a plurality of picture elements arranged in a matrix. The gate wires and the source wires cross each other. Further provided is a driver circuit substrate that drives the liquid crystals by supplying predetermined voltages to the gate and source wires formed on the TFT substrate. In most cases, an electrical connection between such a driver circuit substrate and each of the wires formed on the TFT substrate is made by using a flexible wiring substrate having flexibility.

Meanwhile, due to the recent demand for a reduction in width of the frame of a liquid crystal display device, it has been difficult to ensure sufficient space along the sides of the liquid crystal display panel and the backlight. There have been various proposals presented in order to solve problems attributed to this difficulty.

For example, Patent Literature 1 discloses a liquid crystal display device having a protective member provided on an inner side of a side face of a cover. The technology described in Patent Literature 1 can prevent a flexible substrate and an IC chip from being damaged by being touched by an edge of the side face of the cover when the cover is mounted on the back surface of a backlight.

### CITATION LIST

Patent Literature 1
Japanese Patent Application Publication, Tokukai, No. 2009-75337 A (Publication Date: Apr. 9, 2009)

### SUMMARY OF INVENTION

### Technical Problem

With the demand for a reduction in width of the frame, there has been an increased risk of damage to the driver circuit due to an electrical short caused by contact between a wiring pattern surface of the driver circuit substrate and a backlight chassis.

Patent Literature 1 describes using an L-shaped protective member so that the drive circuit substrate 10 does not make contact with the rear frame 13. However, the technique described in Patent Literature 1 not only makes the manufacturing process complex but also fails to overcome the risk of the drive circuit substrate being damaged in contact with the center frame etc. due to vibrations of transportation etc.

A possible example configuration for reducing these risks is the one in which the backlight chassis is provided with protrusions so that the wiring pattern surface of the driver circuit substrate does not make contact with the backlight chassis. FIG. 7 is a diagram showing an example of a cross-section of a display device having such a configuration. The display device 7 shown in FIG. 7 has a driver circuit substrate (source substrate 41) that supplies predetermined voltages to source wires. The source substrate 41 is connected to a liquid crystal display panel 16 via a flexible wiring substrate (source SOF 40).

The source SOF 40, which has flexibility, is connected to the source substrate 41 in a curved line that extends from the side of the display surface of the liquid crystal display panel 16 along the sides of the liquid crystal display panel and a backlight unit 30, in order that the source substrate 41 is placed at the back of the backlight unit 30 (i.e. at the surface of the backlight unit 30 that faces away from the liquid crystal display panel 16).

The driver circuit has its wiring pattern formed on the surface (substrate rear surface 41a) of the source substrate 41 which faces the backlight unit 30. In the example shown in FIG. 7, the backlight unit 30 includes a backlight chassis 36 having a protrusion (pad-shaped part, drawn part) 36a formed to protrude toward the source substrate 41. It should be noted here that the protrusion 36a is designed to make contact with a place on the rear surface of the source substrate 41 where no wiring pattern is formed. That is, the protrusion 36a is designed not to make contact with the wiring pattern of the source substrate 41.

However, since most of the area on the rear surface of the source substrate 41 is occupied by the wiring pattern, it is impossible to eliminate the possibility of contact between the protrusion 36a and the wiring pattern on the rear surface of the source substrate 41. Further, a plurality of protrusions 36a formed in such positions as not to make contact with the wiring pattern cannot evenly hold the source substrate 41, so that there is a possibility of a short being caused by damage to the substrate rear surface 41a due to vibrations of transportation etc.

Another possible example configuration is the one in which an insulating sheet is provided so that the wiring pattern on the substrate rear surface does not make contact with the backlight chassis. FIG. 8 is a diagram showing an example of a cross-section of a display device having such a configuration.

Provided on the surface of the backlight chassis 36 that faces the source substrate 41 and in a position thereon that faces the substrate rear surface 41a is an insulating sheet 37. The display device 8 shown in FIG. 8 uses this insulating sheet 37 to prevent contact between the backlight chassis 36 and the substrate rear surface 41a.

However, such a display device 8 requires the insulating sheet 37, which is quite expensive, and therefore presents a problem of inviting cost increases.

The present invention has been made in view of the foregoing problems, and it is an object of the present invention to provide a display device that, while suppressing cost increases, can prevent contact between a circuit pattern formed on a circuit substrate and a backlight chassis.

### Solution to Problem

In order to solve the foregoing problems, a display device according to an aspect of the present invention includes: a chassis; a circuit substrate having a surface facing the chassis with a circuit pattern formed on the surface and having a part held with respect to the chassis, the chassis having a projecting part with which an edge of the circuit substrate makes contact when the circuit substrate is displaced toward the chassis.

### Advantageous Effects of Invention

An aspect of the present invention makes it possible to prevent contact between the circuit pattern and the chassis while suppressing cost increases.

### BRIEF DESCRIPTION OF DRAWINGS

FIG. 1 is a set of cross-sectional views (a) and (b) of a display device according to an embodiment of the present invention, (a) of FIG. 1 showing an enlargement of a cross-section of the display device, (b) of FIG. 1 showing a further enlargement of the encircled part of (a) of FIG. 1.

FIG. 2 is an exploded perspective view schematically showing a configuration of a display device according to an embodiment of the present invention.

FIG. 3 is a diagram of the display device of FIG. 2 as seen from the back.

FIG. 4 is an enlarged view of the display device shown in FIG. 3, with an enlargement of the dotted framed part of the display device of FIG. 3.

FIG. 5 is a set of cross-sectional views (a) and (b) of the display device of FIG. 4 taken along the line B-B, (a) of FIG. 5 showing how it looks when a wire holder is opened (released state), (b) of FIG. 5 showing how it looks when the wire holder is closed (stowed state).

FIG. 6 is an enlarged view of the display device of FIG. 3, with an enlargement of the thick-framed part of the display device of FIG. 3.

FIG. 7 is a diagram showing an example of a cross-section showing an internal configuration of a display device according to a comparative example.

FIG. 8 is a diagram showing another example of a cross-section showing an internal configuration of a display device according to a comparative example.

FIG. 9 is an enlarged view of the upper right part of the display device of FIG. 3.

FIG. 10 is a diagram showing a backlight chassis of the display device of FIG. 3.

FIG. 11 is a diagram showing a backlight chassis of a display device according to another embodiment of the present invention.

FIG. 12 is an enlarged view of the upper right part of the backlight chassis of FIG. 11.

FIG. 13 is a cross-sectional view of a display device according to another embodiment of the present invention, showing a cross-section of the display device in a case where the inclined surfaces of two drawn parts are in positions that face each other.

### DESCRIPTION OF EMBODIMENTS

### Embodiment 1

An embodiment of the present invention is described below with reference to the drawings.

(Configuration of a Display Device 10 as Schematically Described)

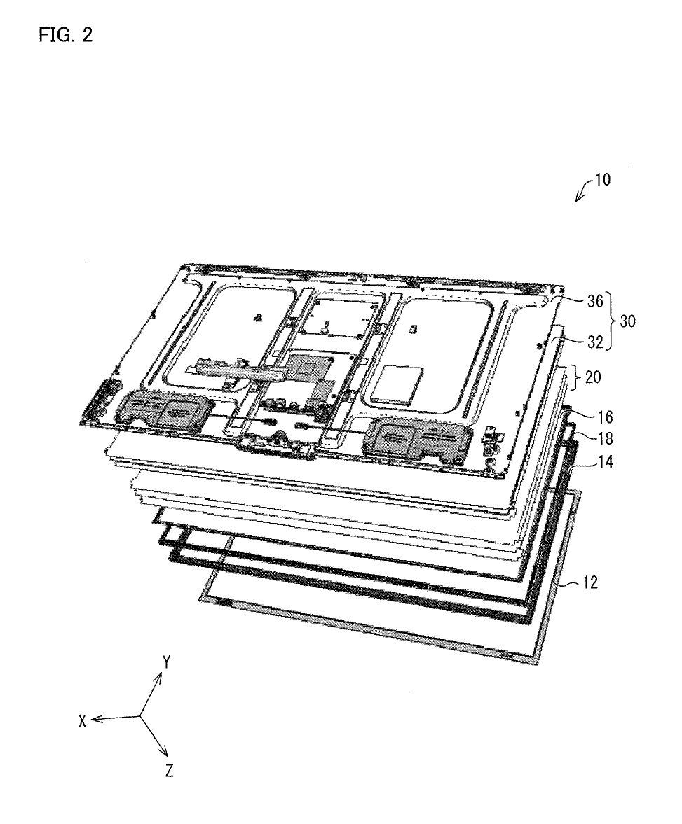

First, a configuration of a display device 10 according to the present embodiment is schematically described with reference to FIG. 2. FIG. 2 is an exploded perspective view schematically showing a configuration of a display device 10 according to an embodiment of the present invention. In particular, FIG. 2 shows the configuration of the display device 10 as viewed from the back surface side. In the description that follows, it is assumed that the display device 10 has its front side (i.e. the side where the picture appears; sometimes referred to also as “front surface side”) facing the region in the drawings in which the z coordinate is positive and the display device 10 has its rear side (sometimes referred to also as “back surface side”) facing the region in the drawings in which the z coordinate is negative.

The display device 10 shown in FIG. 2 is a so-called television receiver which includes a tuner (not illustrated) and a display and which, by replaying content received by the tuner and by causing the display to display the picture represented by the content, allows a user to view the content.

As shown in FIG. 2, the display device 10 includes a bezel 12, a frame 14, a liquid crystal display panel 16, a panel guide 18, optical sheets 20, and a backlight unit 30. In actuality, the display device 10 includes another component, for example a back cover that protects the back surface of the display device 10. However, such a component is not illustrated or described here.

The bezel 12 is attached to the front surface of the frame 14. The bezel 12 is provided for protecting the surface of the frame 14 and improving the appearance of the display device 10. The bezel 12 used here is one made of metal such as aluminum, but a bezel made of a non-metallic material such as resin may be used instead.

The frame 14 supports the display panel 16. Specifically, the frame 14 has a frame part having an opening at the front that corresponds in size to the display region of the liquid crystal display panel 16, and it is this frame part that supports the outer edge of the liquid crystal display panel 16 (i.e. the part of the liquid crystal display panel 16 that is outside of the display region). The frame 14 used here is one made of metal such as aluminum.

The liquid crystal display panel 16 includes a TFT (thin-film transistor) substrate, a color filter, a polarization filter, etc. The TFT substrate includes a glass substrate and a plurality of TFT (thin-film transistor) liquid crystal pixels formed on the glass substrate and connected to a grid-like matrix of wires constituted by gate wires and source wires. In this liquid crystal display panel 16, a display drive circuit (not illustrated) causes a data signal corresponding to a picture signal to be written to each TFT liquid crystal pixel. This causes the amount of backlight that is transmitted through each TFT liquid crystal pixel to be adjusted in the liquid crystal display panel 16, whereby a picture corresponding to the picture signal is displayed.

The panel guide 18 is fitted onto the rear side of the frame 14. The panel guide 18 supports the liquid crystal display panel 16 so that the liquid crystal display panel 16 is supported in a predetermined place on the inner side of the frame 14. The panel guide 18 used here is one made of a non-metallic material such as resin.

The optical sheets 20 are provided in such a manner as to be sandwiched between the liquid crystal display panel 16 and a backlight panel 32. These optical sheets 20 are provided for adjusting the properties of backlight that enters the liquid crystal display panel 16. For example, the optical sheets 20 include a plurality of sheet-like optical members such as a diffusion panel, a diffusion sheet, a lens sheet, and a polarization reflective sheet.

The backlight unit 30, provided at the back of the liquid crystal display panel 16, makes backlight shine on the display panel 16. Specifically, the backlight unit 30 includes the backlight panel 32, an LED substrate 34 (not illustrated), and a backlight chassis (chassis) 36.

The backlight panel 32 is provided at the back of the liquid crystal display panel 16. This backlight panel 32 is a so-called light guide plate that causes backlight having entered the backlight panel 32 through a side part thereof to be guided to the liquid crystal display panel 16.

The backlight chassis 36 supports the backlight panel 32 by the back surface side of the backlight panel 32. The backlight chassis 36 used here is one made of metal such as aluminum.

The LED substrate 34 includes an LED array 35 (not illustrated) serving as a light source and a LED drive circuit (not illustrated) that drives the LED array 35. The LED substrate 34 is provided to a side part of the backlight panel 32, and backlight enters the backlight panel 32 through this side part. In the present embodiment, the LED substrate 34 is provided to the lower side part of the backlight panel 32 (which faces the region in the drawings in which the y coordinate is negative). However, this does not imply any limitation.

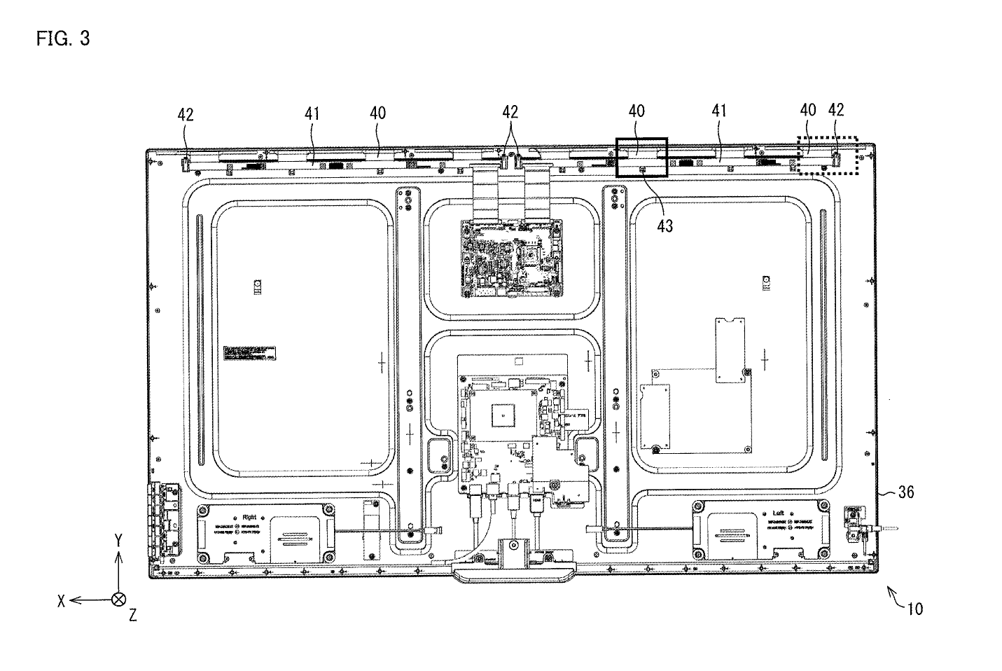

FIG. 3 is an overhead view of the display device 10 of FIG. 2 as seen from the back. As shown in FIG. 3 the liquid crystal display panel 16 is in the shape of a rectangle that has four sides, to the upper long one (facing the region in which the y coordinate is positive) of which one end of each of a plurality of source SOFs (flexible wiring substrates) 40 is connected. Further, the other end of each of the four source SOFs 40 is connected to a single source substrate (circuit substrate) 41. It should be noted that the number of source SOFs 40 that are connected to a single source substrate 41 is not to be limited to this. Further, although the present embodiment is described by taking, as an example, the case where the source SOFs 40 are connected to the upper long side of the liquid crystal display panel 16, the present invention is not to be limited to such an example. The source SOFs 40 may be connected to any of the four sides of the liquid crystal display panel 16. The source substrate 41 and the source SOFs 40 will be described later.

Further, the display device 10 has a wire holder (holding member) 42 that holds a source substrate 41. The wire holder 42 is placed on the back surface side of the backlight chassis 36. As shown in FIG. 3, each wire holder 42 holds a source substrate 41 at either end of a long side of the source substrate 41. Further, although, in the example shown in FIG. 3, there are two source substrates 41 and the display device 10 is provided with four wire holders 42, the number of source substrates 41 and the number of wire holders 42 are not limited to this.

(Wire Holder 42)

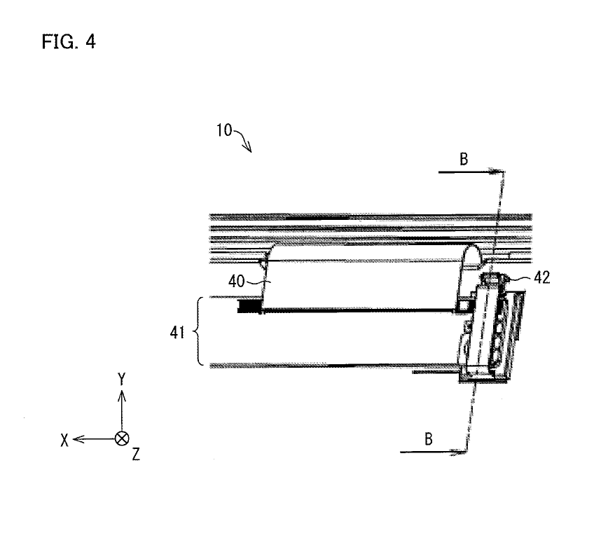

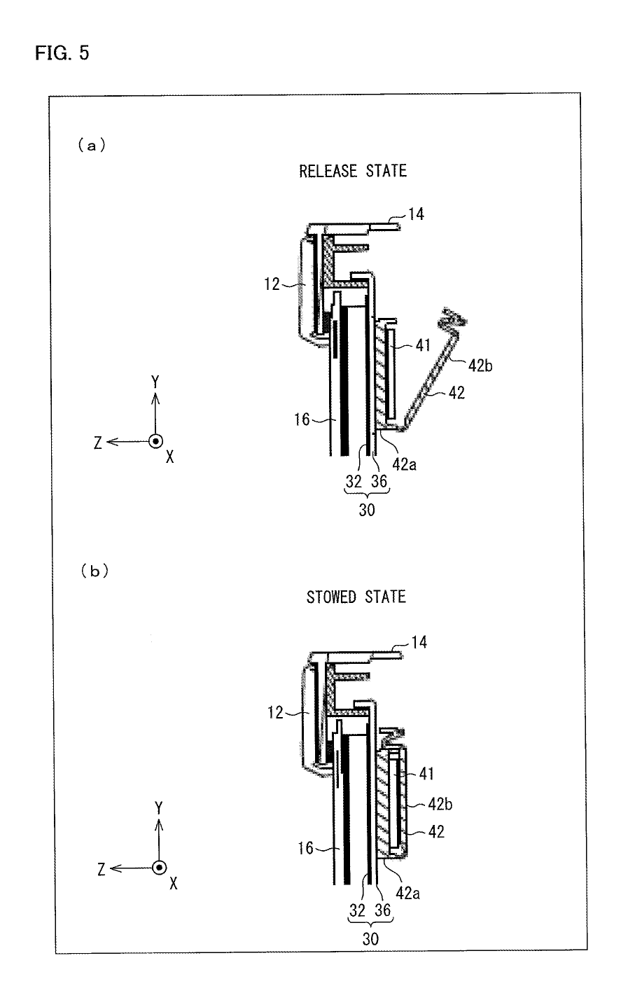

FIG. 4 is an enlarged view of the dotted framed part of the display device 10 of FIG. 3. FIG. 5 is a set of cross-sectional views (a) and (b) of the display device of FIG. 4 taken along the line B-B, (a) of FIG. 5 showing how it looks when a wire holder 42 is opened (released state), (b) of FIG. 5 showing how it looks when the wire holder 42 is closed (stowed state).

As shown in FIGS. 4 and 5, the wire holder 42 has a posterior portion 42a and an anterior portion 42b. The wire holder 42 holds the source substrate 41 between the posterior portion 42a and the anterior portion 42b.

By having such a wire holder 42, the display device 10 can securely position either end of a source substrate 41 with respect to the backlight chassis 36.

Further, if any of the after-mentioned source SOFs 40 is deformed under pressure or through expansion under heat, the source substrate 41 may be shifted or bent by the deformation. Further, the source substrate 41 may also be shifted by vibrations of transportation etc. In such a case, fixing of the source substrate 41 to the backlight chassis 36 with screws etc. may cause the source substrate 41 to be broken or cracked under pressure due to the deformation and/or movement of the source substrate 41. However, the wire holder 42, which simply clamps the source substrate 41, can holds the source substrate 41 without putting extra pressure upon the source substrate 41 even if the source substrate 41 deforms and/or moves.

Further, in a case where a screw or the like is used as a holding member for a source substrate 41, the screw or the like needs to be attached to the backlight chassis 36 when the source substrate 41 is attached to the display device 10. However, a wire holder 42 can be attached to the backlight chassis 36 at any time before a source substrate 41 is attached.

The use of a wire holder 42 as a holding member for a source substrate 41 increases the degree of freedom in the manufacturing process, thus making it possible to improve assembly accuracy.

(Source Substrate 41)

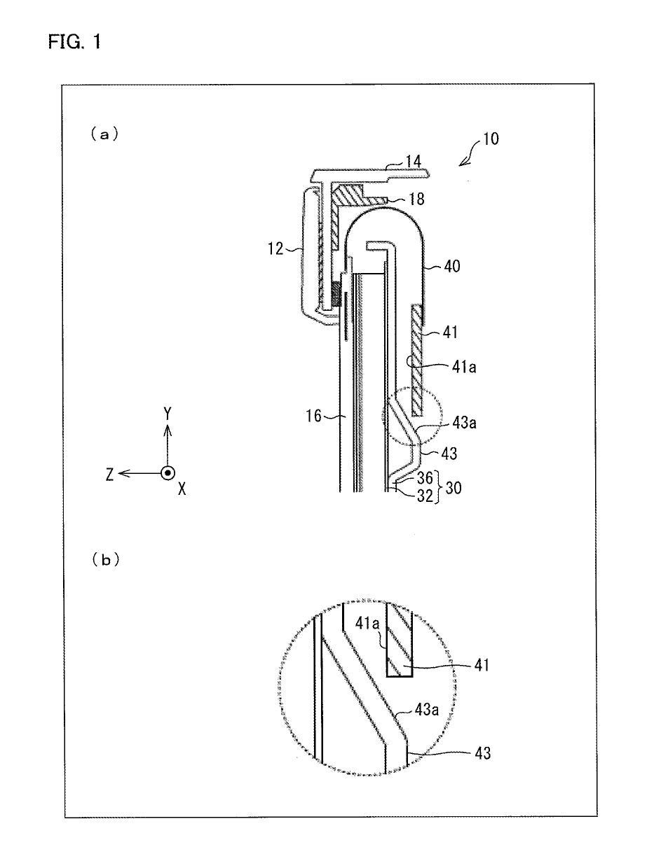

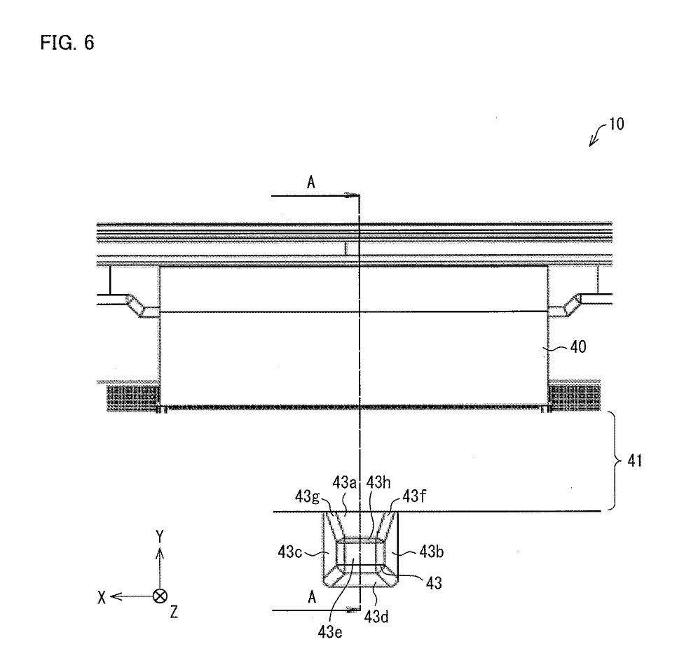

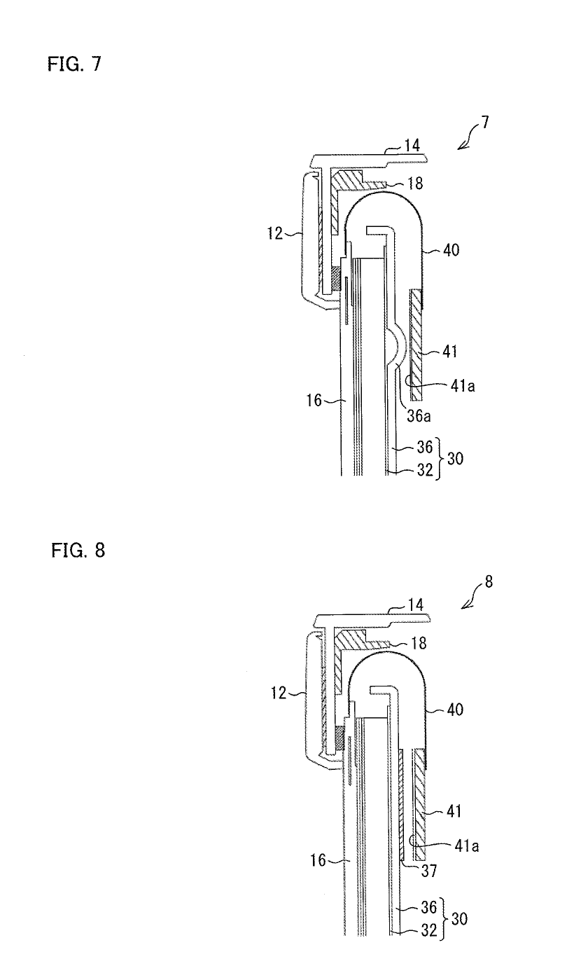

FIG. 6 is an enlarged view of the display device of FIG. 3, with an enlargement of the thick-framed part of the display device of FIG. 3. (a) of FIG. 1 is a cross-sectional view of a surface taken along the line A-A in the enlarged view of the display device in FIG. 6, and (b) of FIG. 1 shows a further enlargement of the encircled part of (a) of FIG. 1.

As shown in FIG. 1, the source substrate 41 is connected to the liquid crystal display panel 16 by an SOF (system-on-film) packaging method. It should be noted here that the SOF packaging method is a method in which a connection to the liquid crystal display panel 16 is made by using a flexible wiring substrate such as a polyimide film.

The source substrate 41 has an elongate shape, e.g. a rectangular shape as shown in FIG. 3, and is placed along an outer edge of the liquid crystal display panel 16. Formed on the surface (substrate rear surface 41a) of the source substrate 41 that faces the backlight unit 30 is a wiring pattern of a source driver.

(Source SOF 40)

A source SOF 40 is a printed wiring substrate for electrically connecting a source substrate 41 and a source wire formed on the liquid crystal display panel 16. As shown in FIG. 1, a source SOF 40 is connected to a source substrate 41 in a curved line that extends from the side of the display surface of the liquid crystal display panel 16 to the back of the backlight unit 30, in order that the source substrate 41 is placed at the back of the backlight unit 30 (i.e. at the surface of the backlight unit 30 that faces away from the liquid crystal display panel 16).

By thus causing the source SOF 40 to be bent in a folded manner so that the source substrate 41 is placed at the back of the backlight unit 30, the bezel 12 of the display device 10 can be formed small in width. That is, a reduction in width of the frame can be achieved.

(Backlight Chassis 36)

The backlight chassis 36 is formed with a drawn part (projecting part) 43 that projects from the backlight chassis 36 toward the source substrate 41. As shown in (b) of FIG. 1, the drawn part 43 has an inclined surface (contact surface) 43a. Further, as shown in (b) of FIG. 1, the inclined surface 43a is formed to be parallel to that one of the two long sides of the source substrate 41 to which the source SOF 40 is not connected (side facing the region in which the y coordinate is negative, edge, lower end, simply referred to as “lower side”). That is, the inclined surface 43a is formed so that a line normal to the inclined surface 43a is orthogonal to the lower side of the source substrate 41. More specifically, the inclined surface 43a is formed so that the angle between the inclined surface 43a and the substrate rear surface 41a is larger than 0 degree and smaller than 90 degrees. Further, the angle between the inclined surface 43a and a line normal to the substrate rear surface 41a is preferably about 45 degrees.

This causes the lower side of the source substrate 41 and the inclined surface 43a to make line contact with each other when the source substrate 41 is displaced (bent, shifted). This disperses the pressure that is applied to the source substrate 41, thus making it possible to prevent the source substrate 41 from being worn or damaged.

Further, as shown in (a) of FIG. 1, the drawn part 43 has a trapezoidal cross-section, and is formed integrally with the backlight chassis 36. As shown in FIG. 6, the drawn part 43 has a substantially rectangular surface (upper surface) 43e raised from the backlight chassis 36 toward the source substrate 41. The drawn part 43 has the aforementioned inclined surface 43a, a surface (surface facing the region in which the y coordinate is negative) 43d facing the inclined surface 43a, and right and left side surfaces (surfaces facing each other along the x axis) 43b and 43c. Further, the drawn part 43 has a sloped surface 43f. The sloped surface 43f is a surface where the inclined surface 43a and the side surface 43b are connected to each other. The sloped surface 43f is formed to prevent a dihedral angle from being formed when the inclined surface 43a and the side surface 43b are directly connected to each other. Similarly, the drawn part 43 has a sloped surface 43g. The sloped surface 43g is a surface where the inclined surface 43a and the side surface 43c are connected to each other. The sloped surface 43g is formed to prevent a dihedral angle from being formed when the inclined surface 43a and the side surface 43c are directly connected to each other. Further, the drawn part 43 has a sloped surface 43h. The sloped surface 43h is a surface where the inclined surface 43a and the upper surface 43e are connected to each other. The sloped surface 43h is formed to prevent a dihedral angle from being formed when the inclined surface 43a and the upper surface 43e are directly connected to each other. That is, the sloped surfaces 43f, 43g, and 43h are parts chamfered obliquely from the inclined surface 43a.

If there is a dihedral angle around the inclined surface 43a of the drawn part 43, the dihedral angle makes point contact with the lower side of the source substrate 41, thus posing a risk of wearing or damaging the source substrate 41. The pressure that can be generated between the lower side of the source substrate 41 and the drawn part 43 can be reduced by forming chamfered parts (sloped surfaces 43f, 43g, and 43h) around the inclined surface 43a as in the present embodiment. This makes it possible to prevent the source substrate 41 from being worn or damaged.

Further, as shown in FIGS. 3, 9, and 10, there are four such drawn parts 43 formed for each source substrate 41. It should be noted that the number of drawn parts 43 is not to be limited to this number, but only needs to be such a number that it is possible to prevent the backlight chassis 36 and the wiring pattern of the substrate rear surface 41a from making contact when the source substrate is bent.

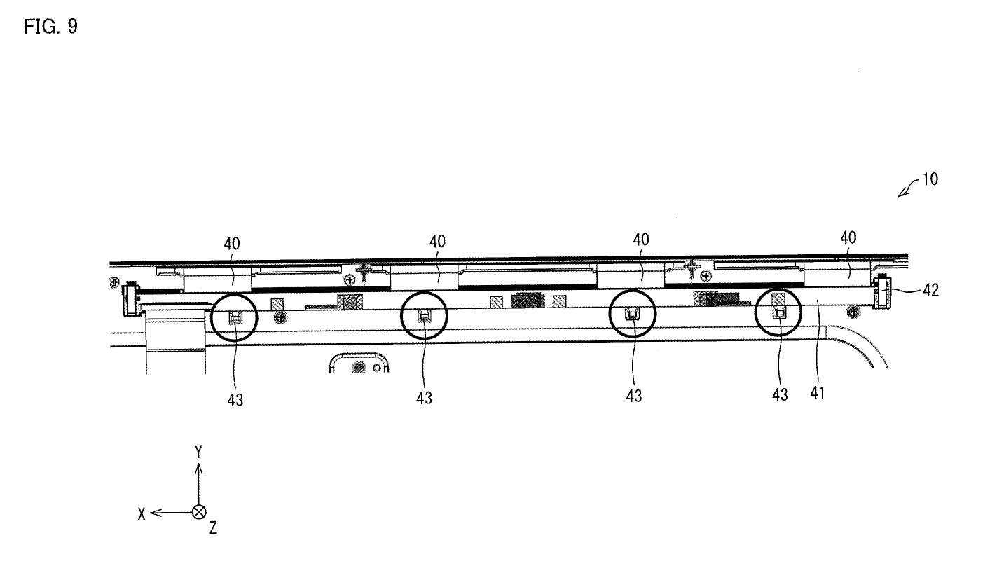

Further, of the four drawn parts 43 shown in FIG. 9, the first to third drawn parts 43 as counted from the left are placed in positions that correspond to the source SOFs 40, respectively (in the same positions on the x axis as those in which the source SOFs 40 are placed and in positions closer to the region in which the y coordinate is negative than those positions on the y axis in which the source SOFs 40 are placed). This allows the drawn parts 43 to more suitably hold the source substrates 41 with the elastic force of the source SOFs 40.

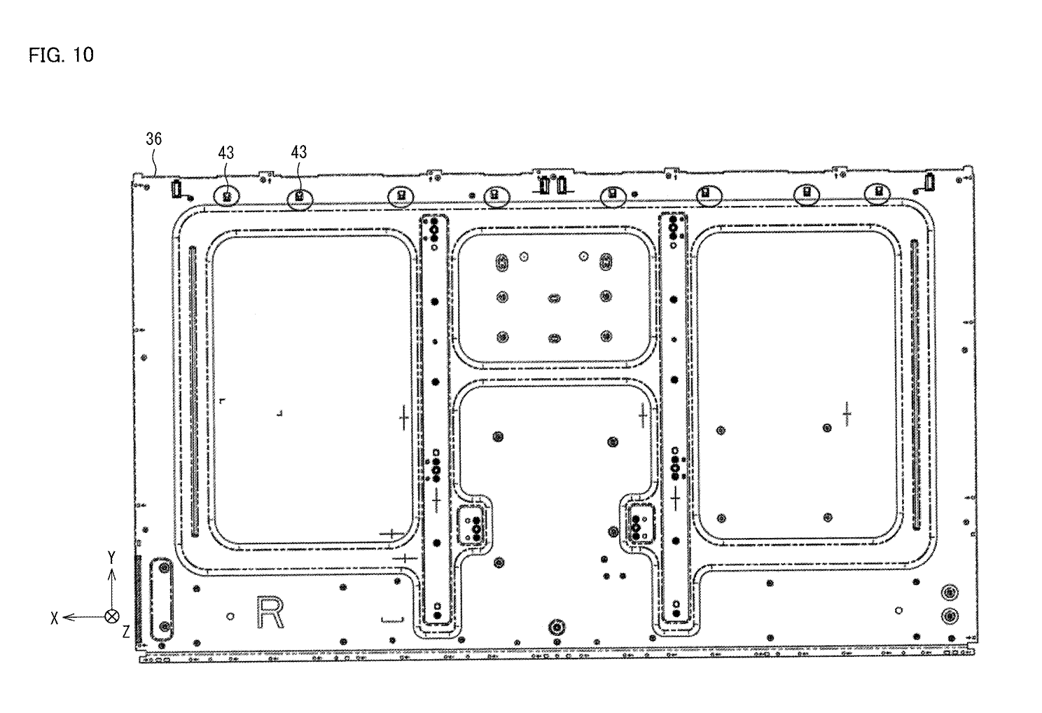

Further, the positions in which the drawn parts 43 are placed are not to be limited to those positions shown in FIGS. 9 and 10. The drawn parts 43 may for example be placed at such intervals as to be able to prevent the source substrates 41 from making contact with the backlight chassis 36 (for examples, at intervals at most half as long as or the shortest one of the intervals at which the source substrates 41 make contact with the backlight chassis 36 under their own weights).

Further, the shape of each of the drawn parts 43 is not to be limited to the aforementioned shape, and the drawn parts 43 need only be formed so as to be able to hold the source substrate 41. For example, the shape of each of the drawn parts 43 may be a semispherical shape.

Further, as mentioned above, the drawn parts 43 may be the ones formed integrally with the backlight chassis 36 by projecting from the backlight chassis 36, or may be the ones formed by members on the backlight chassis 36 separately from the backlight chassis 36.

As described above, the display device 10 includes: a backlight chassis 36; and a source substrate 41 having a surface (substrate rear surface 41a) facing the backlight chassis 36 with a circuit pattern formed on the surface and having a part held with respect to the backlight chassis 36. The backlight chassis 36 has a drawn part (projecting part) 43 with which a lower side (edge) of the source substrate 41 makes contact when the source substrate 41 is displaced toward the backlight chassis 36.

In such a configuration, the backlight chassis 36 has a drawn part 43, such that the lower side of the source substrate 41 makes contact with the inclined surface 43a of the drawn part 43 when the source substrate 41 is displaced toward the backlight chassis 36 due to external pressure, thermal deformation, or the like. Therefore, even if the source substrate 41 is displaced, the source substrate 41 will not make contact with any part of the backlight chassis 36 other than the inclined surface 43a. Further, since the drawn part 43 is in contact with the edge of the source substrate 41, even if the source substrate 41 is displaced, contact between the backlight chassis 36 and the circuit pattern of the source substrate 41 can be prevented. Further, since the drawn part 43 can be achieved by a simple configuration, the drawn part 43 hardly invites cost increases.

Further, the display device 10, in which the drawn part 43 is formed integrally with the backlight chassis 36, can prevent contact between the backlight chassis 36 and the circuit pattern of the source substrate 41 without needing a new member as the drawn part 43. That is, the display device 10 can both prevent contact between the backlight chassis 36 and the circuit pattern of the source substrate 41 and more effectively suppress cost increases.

Further, since the display device 10 has the wire holder 42, the edge of the source substrate 41 other than both ends makes contact with the drawn part 43 even if the source substrate 41 is bent; therefore the circuit pattern formed on the source substrate 41 will not make contact with the backlight chassis 36. This makes it possible to, while preventing contact between the backlight chassis 36 and the circuit pattern, effectively use the limited amount of space on the source substrate 41 for the circuit pattern.

It should be noted that although a case where the source substrate 41 is placed at the back of the backlight chassis 36 and along a surface parallel to the liquid crystal display panel 16 has been taken as an example, the example does not imply any limitation. In a case where the backlight chassis 36 has a side face part along a side face of the display device 10 and the source substrate 41 is placed along the side face part of the backlight chassis 36, a projecting part that makes contact with the edge of the source substrate 41 needs only be provided on the side face part of the backlight chassis 36.

Further, in a case where there is a possibility that the wiring pattern of the source substrate 41 makes contact with a member other than the backlight chassis 36, the member needs only be provided with a projecting part that makes contact with the edge of the source substrate 41.

Further, in the foregoing description, it was assumed that the drawn part 43 makes contact when the source substrate 41 is displaced. However, there may be a configuration in which in a case where the source substrate 41 is in a fixed place or in a situation where the source substrate 41 is not bent, the drawn part 43 makes contact with the edge of the source substrate 41.

### Embodiment 2

Another embodiment (Embodiment 2) of a display device according to the present invention is described below with reference the drawings. A display device 10′ according to the present embodiment differs from the display device 10 according to Embodiment 1 in that the former does not include a backlight chassis 36 having a drawn part 43 with which the lower side of a source substrate 41 makes contact, but includes a backlight chassis 36′ having a drawn part 43 with which the lower side of a source substrate 41 makes contact and a drawn part 44 with which the upper side of the source substrate 41 makes contact. Since the present embodiment differs solely in this regard from Embodiment 1, only the point of difference is described below, and the same members are given the same reference signs, and as such, are not described here.

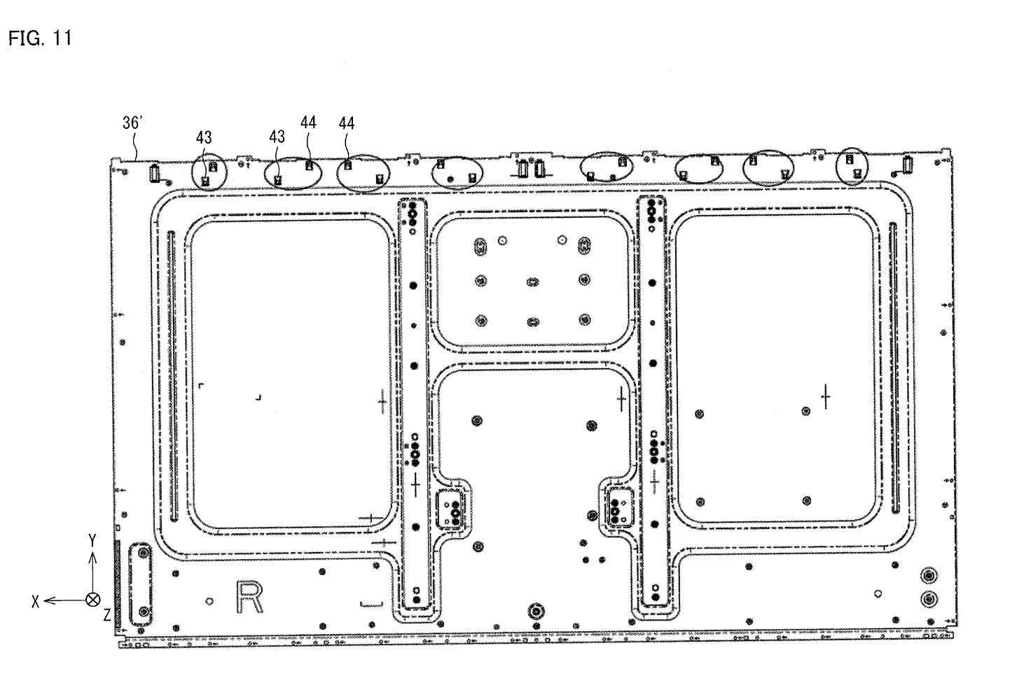

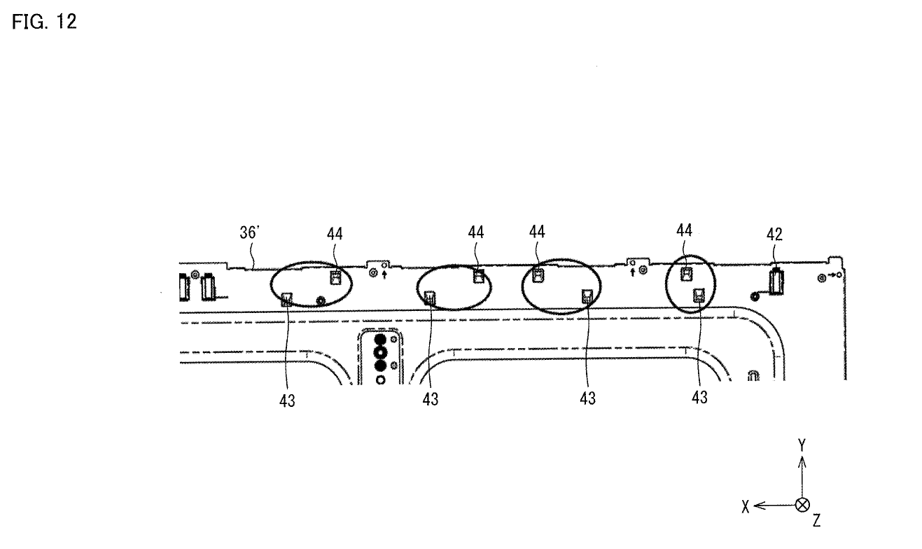

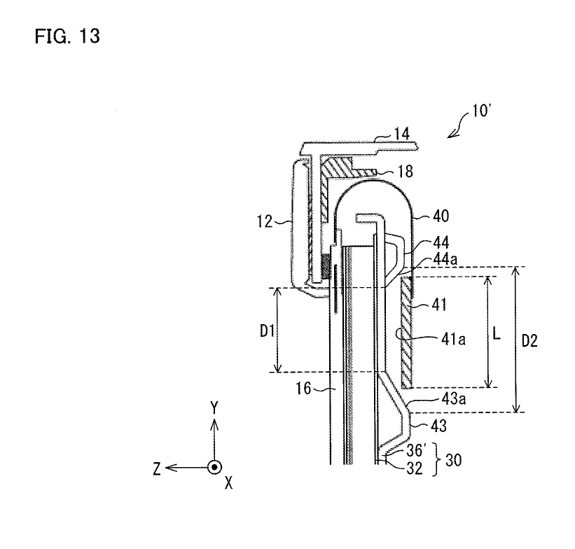

FIG. 11 is a diagram showing the backlight chassis 36′ of the display device 10′ according to the present embodiment. Further, FIG. 12 is an enlarged view of the upper right part of the backlight chassis 36′ of FIG. 11. Further, FIG. 13 is a cross-sectional view of a display device according to another embodiment of the present invention, showing a cross-section of the display device in a case where the inclined surface 43a of a drawn part 43 and the inclined surface 44a of a drawn part 44 are in positions that face each other (in the same positions on the x axis).

(Backlight Chassis 36′)

As shown in FIGS. 11 through 13, the backlight chassis 36′ is formed with drawn parts (first projecting parts) 43 and drawn parts (second projecting parts) 44 that project from the backlight chassis 36′ toward the source substrate 41. As shown in FIG. 13, each of the drawn parts 44 has an inclined surface (contact surface) 44a. Of the surfaces of the drawn part 44, the inclined surface 44a is formed to face the inclined surface 43a of the drawn part 43 (to face the region in FIG. 13 in which the y coordinate is negative). Further, as shown in FIG. 13, the inclined surface 44a is formed to be parallel to that one of the two long sides of the source substrate 41 to which the source SOF 40 is connected (side facing the region in which the y coordinate is positive, upper end, simply referred to as “upper side”). That is, the inclined surface 44a is formed so that a line normal to the inclined surface 44a is orthogonal to the upper side of the source substrate 41. More specifically, the inclined surface 44a is formed so that the angle between the inclined surface 44a and the substrate rear surface 41a is larger than 0 degree and smaller than 90 degrees. Further, the angle between the inclined surface 44a and a line normal to the substrate rear surface 41a is preferably about 45 degrees.

This causes the lower side of the source substrate 41 and the inclined surface 43a to make line contact with each other when the source substrate 41 is displaced (bent, shifted). Furthermore, this causes the upper side of the source substrate 41 and the inclined surface 44a to make line contact with each other. This disperses the pressure that is applied to the source substrate 41, thus making it possible to more suitably prevent the source substrate 41 from being worn or damaged.

Further, as shown in FIGS. 11 through 13, each of the drawn parts 44 has a trapezoidal cross-section. The drawn part 44 may be formed integrally with the backlight chassis 36′, or may be formed as a separate member. In the case where the drawn part 44 is formed integrally with the backlight chassis 36′, it is possible to prevent contact between the backlight chassis 36′ and the circuit pattern of the source substrate 41 without needing a new member as the drawn part 44. That is, it is possible to both prevent contact between the backlight chassis 36′ and the circuit pattern of the source substrate 41 and more effectively suppress cost increases.

Further, the drawn part 44 may have a similar shape to the drawn part 43. That is, the drawn part 44 may have a substantially rectangular surface (upper surface) raised from the backlight chassis 36′ toward the source substrate 41. The drawn part 44 may have the aforementioned inclined surface 44a, a surface (surface facing the region in which the y coordinate is negative) facing the inclined surface 43a, and right and left side surfaces (surfaces facing each other along the x axis). Furthermore, the drawn part 44 may have parts chamfered obliquely from the inclined surface 44a. Specifically, the drawn part 44 may have (1) a sloped surface which is a surface where the inclined surface 44a and each of the right and left side surfaces are connected to each other and which is formed to prevent a dihedral angle from being formed when the inclined surface 44a and each of the right and left side surfaces are directly connected to each other and (2) a sloped surface which is a surface where the inclined surface 44a and the upper surface are connected to each other and which is formed to prevent a dihedral angle from being formed when the inclined surface 44a and the upper surface are directly connected to each other.

It should be noted that the shape of each of the drawn parts 44 is not to be limited to the aforementioned shape, and the drawn parts 44 need only be formed so as to be able to hold the source substrate 41. For example, the shape of each of the drawn parts 44 may be a semispherical shape.

As described above, the display device 10′ includes: a backlight chassis 36′; and a source substrate 41 having a surface (substrate rear surface 41a) facing the backlight chassis 36′ with a circuit pattern formed on the surface and having a part held with respect to the backlight chassis 36′. The backlight chassis 36′ has a drawn part (first projecting part) 43 with which a lower side (lower end) of the source substrate 41 makes contact when the source substrate 41 is displaced toward the backlight chassis 36′ and a drawn part 44 (second projecting part) 44 with which an upper side (upper end) of the source substrate 41 makes contact when the source substrate 41 is displaced toward the backlight chassis 36′.

In such a configuration, the lower side (edge, lower end) of the source substrate 41 makes contact with the inclined surface 43a of the drawn part 43 when the source substrate 41 is displaced toward the backlight chassis 36′ due to external pressure, thermal deformation, or the like. Further, the upper side (upper end) of the source substrate 41 makes contact with the inclined surface 44a of the drawn part 44. Therefore, even if the source substrate 41 is displaced, the source substrate 41 will not make contact with any part of the backlight chassis 36′ other than the inclined surface 43a or 44a. Further, since the drawn part 44 is in contact with the upper side of the source substrate 41, even if the source substrate 41 is displaced upward, contact between the backlight chassis 36′ and the circuit pattern of the source substrate 41 can be prevented. Further, since the drawn part 44 can be achieved by a simple configuration, the drawn part 44 hardly invites cost increases.

Further, as shown in FIGS. 11 and 12, the drawn parts 44 may be placed in different positions from or the same positions as those of the drawn parts 43 on a long side (along the x axis) of the display device 10′. Further, as shown in FIGS. 11 and 12, the number of drawn parts 44 may be the same as or different from the number of drawn parts 43.

It should be noted here that as shown in FIG. 13, D1 is the distance between the lower end of the inclined surface 43a of the drawn part 43 (i.e. the side of the inclined surface 43a that is connected to the backlight chassis 36′) and the lower end of the inclined surface 44a of the drawn part 44 (i.e. the side of the inclined surface 44a that is connected to the backlight chassis 36′) and the distance along a short side (distance along the y axis) of the display device 10′, and D2 is the distance between the upper end of the inclined surface 43a of the drawn part 43 (i.e. the side of the inclined surface 43a that is connected to the upper surface 43e) and the upper end of the inclined surface 44a of the drawn part 44 (i.e. the side of the inclined surface 44a that is connected to the surface of the drawn part 44 that protrudes toward the source substrate 41) and the distance along a short side (distance along the y axis) of the display device 10′. Further, assuming that L is the width (length along a short side) of the source substrate 41, it is preferable that the drawn parts 43 and 44 of the display device 10′ be formed in such a manner as to satisfy D1<L<D2. This allows the upper and lower sides of the source substrate 41 to make contact with the inclined surfaces 44a and 43a, respectively, even if the source substrate 41 is displaced upward or downward.

(Summary)

A display device according to an aspect of the present invention includes: a chassis (backlight chassis 36); a circuit substrate (source substrate 41) having a surface facing the chassis with a circuit pattern formed on the surface and having a part held with respect to the chassis, the chassis having a projecting part (drawn part 43) with which an edge of the circuit substrate makes contact when the circuit substrate is displaced toward the chassis.

In the foregoing configuration, the chassis has the projecting part, and the edge of the circuit substrate makes contact with the projecting part when the circuit substrate is displaced toward the chassis due to external pressure, thermal deformation, or the like. Therefore, even if the circuit substrate is displaced, the circuit substrate will not make contact with any part of the chassis other than the projecting part. Further, since the projecting part is in contact with the edge of the circuit substrate, even if the circuit substrate is displaced, contact between the chassis and the circuit pattern of the circuit substrate can be prevented. Further, since the projecting part can be achieved by a simple configuration, the projecting part makes it possible to prevent contact between the chassis and the circuit pattern while suppressing cost increases.

Furthermore, the display device according to an aspect of the present invention is preferably configured such that the projecting part is formed integrally with the chassis.

The foregoing configuration makes it possible to prevent contact between the chassis and the circuit pattern of the circuit substrate without needing a new member as the projecting part, i.e. to both prevent contact between the chassis and the circuit pattern of the circuit substrate and more effectively suppress cost increases.

Furthermore, the display device according to an aspect of the present invention is preferably configured such that the projecting part has a contact surface (inclined surface 43a) that is parallel to the edge of the circuit substrate.

In the foregoing configuration, the projecting part has a contact surface that is parallel to the edge of the circuit substrate. As such, when the circuit substrate is bent, the edge of the circuit substrate and the projecting part makes line contact with each other. Therefore, even if the circuit substrate is bent, no extreme pressure will be applied to the circuit substrate. This makes it possible to inhibit the circuit substrate from being worn or damaged.

Furthermore, the display device according to an aspect of the present invention is preferably configured such that the chassis has a projecting part with which a lower end of the circuit substrate makes contact when the circuit substrate is displaced toward the chassis.

In the foregoing configuration, the lower end of the circuit substrate makes contact with the projecting part of the chassis. In such a configuration, even if the circuit substrate is displaced, the circuit substrate will not make contact with any part of the chassis other than the projecting part. Therefore, even if the circuit substrate is displaced, contact between the chassis and the circuit pattern of the circuit substrate can be prevented.

Furthermore, the display device according to an aspect of the present invention is preferably configured such that the chassis has a first projecting part (drawn part 43) with which a lower end of the circuit substrate makes contact when the circuit substrate is displaced toward the chassis and a second projecting part (drawn part 44) with which an upper end of the circuit substrate makes contact when the circuit substrate is displaced toward the chassis.

In the foregoing configuration, the chassis has a first projecting part with which a lower end of the circuit substrate makes contact when the circuit substrate is displaced toward the chassis and a second projecting part with which an upper end of the circuit substrate makes contact when the circuit substrate is displaced toward the chassis. In such a configuration, the lower and upper ends of the circuit substrate make contact with the first and second projecting parts, respectively, when the circuit substrate is displaced toward the chassis due to external pressure, thermal deformation, or the like. Therefore, even if the circuit substrate is displaced, contact between the chassis and the circuit pattern of the circuit substrate can be prevented. Further, since the second projecting part can be achieved by a simple configuration, the second projecting part makes it possible to prevent contact between the chassis and the circuit pattern while suppressing cost increases.

Furthermore, the display device according to an aspect of the present invention may be configured such that: the circuit substrate has an elongate shaped; and the chassis has a holding member (wire holder 42) for holding either end of the circuit substrate.

In the foregoing configuration, the circuit substrate has an elongate shaped, and the chassis has a holding member for holding either end of the circuit substrate. This makes it possible to surely position either end of the circuit substrate with respect to the chassis. Further, the edge of the circuit substrate other than both ends makes contact with the projecting part even if the circuit substrate is bent; therefore the circuit pattern formed on the circuit substrate will not make contact with the chassis.

This makes it possible to, while preventing contact between the chassis and the circuit pattern, effectively use the limited amount of space on the circuit substrate for the circuit pattern.

Furthermore, the display device according to an aspect of the present invention is preferably configured such that: the chassis is a backlight chassis; and the display device includes: a display panel (liquid crystal display panel 16) placed in parallel to the backlight chassis; and a flexible wiring substrate (source SOF 40) having one end connected to the display panel and the other end connected to the circuit substrate.

In the foregoing configuration, the backlight chassis, the display panel, the circuit substrate are placed substantially parallel to each other, and the display panel and the circuit substrate is connected via the flexible wiring substrate. Therefore, this makes it possible to achieve a display device that, while achieving a reduction in width of the frame and a reduction in thickness, can prevent the wiring pattern of the circuit substrate from making contact with the backlight chassis.

Further, a television receiver including the display device, too, is encompassed in the scope of the present invention.

The present invention is not limited to the description of the embodiments above, but may be altered by a skilled person within the scope of the claims. An embodiment based on a proper combination of technical means disclosed in different embodiments is encompassed in the technical scope of the present invention.

### INDUSTRIAL APPLICABILITY

The present invention is applicable to display sections of household appliances such as television receivers and computers.

### REFERENCE SIGNS LIST

10 Display device
12 Bezel
14 Frame
16 Liquid crystal display panel
18 Panel guide
20 Optical sheets
30 Backlight unit
32 Backlight panel
34 LED substrate
35 LED array
36 Backlight chassis (chassis)
40 Source SOF (flexible wiring substrate)
41a Substrate rear surface
42 Wire holder (holding member)
42a Posterior portion
42b Anterior portion
43 Drawn part (projecting part, first projecting part)
43a Inclined surface (contact surface)
43f Sloped surface
43g Sloped surface
43h Sloped surface
10′ Display device
36′ Backlight chassis (chassis)
44 Drawn part (projecting part, second projecting part)

1. A display device comprising:
a chassis;
a circuit substrate having a surface facing the chassis with a circuit pattern formed on the surface and having a part held with respect to the chassis,
the chassis having a projecting part with which an edge of the circuit substrate is able to make contact.

2. The display device as set forth in claim 1, wherein the projecting part is formed integrally with the chassis.

3. The display device as set forth in claim 1, wherein the projecting part has a contact surface that is parallel to the edge of the circuit substrate.

4. The display device as set forth in claim 1, wherein the chassis has a projecting part with which a lower end of the circuit substrate is able to make contact.

5. The display device as set forth in claim 1, wherein the chassis has a first projecting part with which a lower end of the circuit substrate makes contact when the circuit substrate is displaced toward the chassis and a second projecting part with which an upper end of the circuit substrate makes contact when the circuit substrate is displaced toward the chassis.

6. The display device as set forth in claim 1, wherein:
the circuit substrate has an elongate shaped; and
the chassis has a holding member for holding either end of the circuit substrate.

7. The display device as set forth in claim 1, wherein:
the chassis is a backlight chassis; and
the display device includes:
a display panel placed in parallel to the backlight chassis; and
a flexible wiring substrate having one end connected to the display panel and the other end connected to the circuit substrate.

8. A television receiver comprising a display device as set forth in claim 1.
